(19) United States
(12) Patent Application Publication
(10) Pub. No.: US 2025/0147133 A1
(43) Pub. Date: May 8, 2025

(54) PHASE CORRECTION METHOD, PHASE CORRECTION APPARATUS, AND MRI APPARATUS

(71) Applicant: CANON MEDICAL SYSTEMS CORPORATION, Otawara-shi (JP)

(72) Inventors: Masahiro ABE, Yokohama (JP); Shohei HAMANAGA, Nasushiobara (JP); Mitsuhiro BEKKU, Utsunomiya (JP)

(73) Assignee: CANON MEDICAL SYSTEMS CORPORATION, Otawara-shi (JP)

(21) Appl. No.: 18/904,060

(22) Filed: Oct. 1, 2024

(30) Foreign Application Priority Data
Oct. 2, 2023 (JP) 2023-171493

(51) Int. Cl. G01R 33/48; G01R 33/565

(52) U.S. Cl. CPC G01R 33/4818; G01R 33/56554

(57) ABSTRACT

In one embodiment, a phase correction method comprising: acquiring first k-space data acquired in a first readout direction and second k-space data acquired in a second readout direction that is opposite to the first readout direction; weighting first real space data obtained from the first k-space data to generate first adjusted data with a predetermined weighting in which weight coefficients vary depending on a pixel position in a readout direction and become lower in a region where a variance of a phase difference is larger than a predetermined variance; weighting second real space data obtained from the second k-space data to generate second adjusted data with the predetermined weighting; calculating a correction amount for correcting a phase difference; and correcting a phase difference between data that are different from each other in polarity of a gradient pulse in the readout direction during acquisition, by using the correction amount.

### CROSS-REFERENCE TO RELATED APPLICATION

This application claims the benefit of priority of Japanese Patent Application No. 2023-171493, filed on Oct. 2, 2023, the entire contents of which are incorporated herein by reference.

### FIELD

Disclosed Embodiments relate to a phase correction method, a phase correction apparatus, and a magnetic resonance imaging (MRI) apparatus.

### BACKGROUND

An MRI apparatus is an imaging apparatus that magnetically excites nuclear spin of an object placed in a static magnetic field by applying a radio frequency (RF) signal having the Larmor frequency and reconstructs an image on the basis of magnetic resonance (MR) signals emitted from the object due to the excitation.

One of the pulse sequences to be used for imaging an object in an MRI apparatus is an echo planar imaging (EPI) method. In the EPI method, the MRI apparatus acquires MR signal data while reversing the polarity of the readout gradient magnetic field. In this case, due to factors such as eddy currents and spatial non-uniformity of magnetic field strength, a phase difference occurs between respective MR signal data having a plus polarity and a minus polarity of the readout gradient magnetic fields. When adjacent lines in a k-space are filled under the state where the phase difference exists between the MR signal data, N/2 artifacts may occur.

Known methods for reducing the N/2 artifacts include a multi-order phase correction method and an Ahn-Cho method in which first-order phase correction and zeroth-order phase correction are performed. However, in the conventional phase correction methods, in some cases, the phase correction is not successfully performed, which causes image degradation in a region of interest for diagnosis and an examination, for example.

### BRIEF DESCRIPTION OF THE DRAWINGS

In the accompanying drawings:

FIG. 1 is a block diagram illustrating a configuration of a phase correction apparatus according to one embodiment;

FIGS. 2A, 2B, 2C, 2D, and 2E are schematic graphs illustrating a phase difference in a k-space and a real space;

FIG. 3A is a schematic diagram illustrating data having opposite polarities of a gradient pulse in a readout direction during acquisition;

FIG. 3B is a schematic diagram illustrating real space data obtained by performing one-dimensional Fourier transform on the data of FIG. 3A;

FIG. 4A and FIG. 4B are schematic diagrams illustrating unsuccessful phase correction in a region of interest;

FIG. 5 is a flowchart illustrating an operation of a phase correction method according to the embodiment;

FIG. 6 is a schematic diagram illustrating k-space phase encoding lines and the readout direction of the k-space data;

FIG. 7A and FIG. 7B are schematic diagrams illustrating adjusted data according to the embodiment;

FIGS. 8A, 8B, and 8C are schematic graphs for respectively illustrating first to third weighting aspects according to the first embodiment;

FIG. 9A and FIG. 9B are schematic diagrams illustrating a first weighting aspect according to the first embodiment and its application case;

FIG. 10A and FIG. 10B are schematic diagrams illustrating a second weighting aspect according to the first embodiment and its application case;

FIG. 11 is a schematic diagram illustrating a fourth weighting aspect according to the first embodiment;

FIG. 12A and FIG. 12B are schematic diagrams illustrating a case of phase correction by the fourth weighting aspect according to the first embodiment;

FIG. 13 is a schematic diagram illustrating weighting aspects in the phase correction method according to the second embodiment;

FIG. 14 is a block diagram illustrating an overall configuration of an MRI apparatus according to the embodiment;

FIG. 15 is a block diagram illustrating a configuration of the MRI apparatus that includes the phase correction apparatus according to the embodiment;

FIG. 16 is a flowchart illustrating a first operation to be performed by the MRI apparatus according to the embodiment; and

FIG. 17 is a flowchart illustrating a second operation to be performed by the MRI apparatus according to the embodiment.

### DETAILED DESCRIPTION

Hereinbelow, a description will be given of respective embodiments of a phase correction method, a phase correction apparatus, and an MRI apparatus by referring to the accompanying drawings.

In one embodiment, a phase correction method comprising: acquiring first k-space data acquired in a first readout direction and second k-space data acquired in a second readout direction that is opposite to the first readout direction; weighting first real space data to generate first adjusted data with a predetermined weighting, wherein weight coefficients in the predetermined weighting vary depending on a pixel position in a readout direction and become lower in a region where a variance of a phase difference is larger than a predetermined variance, the first real space data being obtained by performing one-dimensional Fourier transform on the first k-space data; weighting second real space data to generate second adjusted data with the predetermined weighting, the second real space data being obtained by performing one-dimensional Fourier transform on the second k-space data; calculating a correction amount for correcting a phase difference between the first adjusted data and the second adjusted data; and correcting a phase difference between data that are different from each other in polarity of a gradient pulse in the readout direction during acquisition, by using the correction amount.

### (Phase Correction Apparatus)

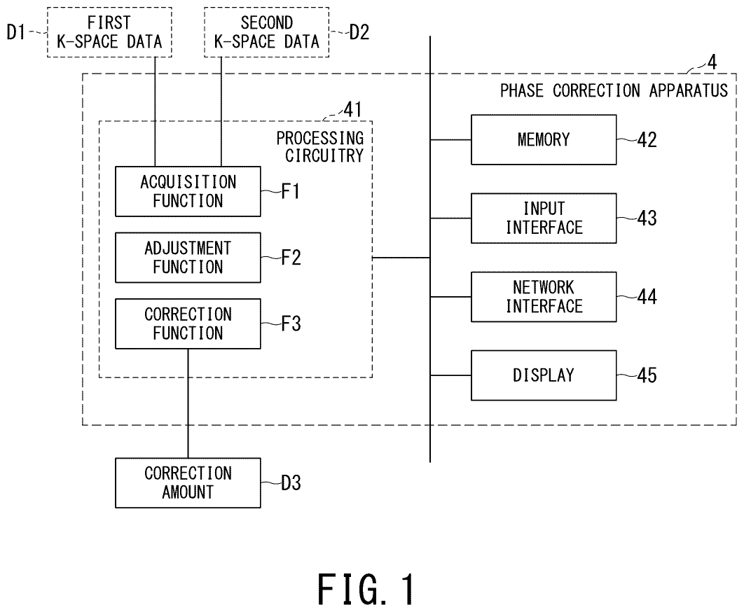

FIG. 1 is a block diagram illustrating a configuration of a phase correction apparatus 4 according to one embodiment. The phase correction apparatus 4 performs phase correction between data, which are opposite to each other in polarity of the gradient pulse in the readout direction, so as to reduce the phase difference in the region of interest for diagnosis and an examination, for example. Hereinafter, the gradient pulse in the readout direction is abbreviated as the readout gradient pulse.

As shown in FIG. 1, the phase correction apparatus 4 includes processing circuitry 41 and a memory 42. The phase correction apparatus 4 may further include an input interface 43, a network interface 44, and a display 45.

The display 45 is composed of a general display device such as a liquid crystal display, an OLED (Organic Light Emitting Diode) display panel, a plasma display panel, and an organic EL (Electro Luminescence) panel. The display 45 displays various information items under the control of the processing circuitry 41. The display 45 may be a GUI (Graphical User Interface) that is a display device and can receive various inputs via a user's operation, as exemplified by a touch panel.

The network interface 44 implements various information communication protocols in accordance with the aspect of the network. The network interface 44 controls communication on the basis of various protocols and is connectable to the network by wire or wirelessly. The network interface 44 can exchange various data such as MR signal data of an object between the network and the memory 42.

The input interface 43 includes: an input device that can be operated by a user; and an input circuit configured to receive inputs from the input device. The input device is achieved by a trackball, a switch, a mouse, a keyboard, a touch pad where an input operation is performed by touching its operation screen, a touch screen in which a display screen and a touch pad are integrated, a non-contact input device using an optical sensor, and a voice input device, for example. When the input device is operated by the user, the input circuit generates an instruction signal corresponding to the operation, and outputs the instruction signal to the processing circuitry 41. The input interface 43 may be a touch panel in which the input device is integrated with the display.

The memory 42 is composed of at least one recording medium that can be read by a processor, as exemplified by: a semiconductor memory element such as a RAM (Random Access Memory) and a flash memory; a hard disk; and an optical disc. The memory 42 may be composed of a portable medium such as a USB (Universal Serial Bus) memory and a DVD (Digital Video Disk). The memory 42 can exchange various data, such as MR signal data of an object, via a portable medium. The memory 42 stores various processing programs to be executed by the processing circuitry 41 and data necessary for executing the programs, for example.

The processing circuitry 41 implements a function of integrally controlling the phase correction apparatus 4. The processing circuitry 41 is a processor that implements various functions by reading out and executing various processing programs stored in the memory 42 or directly incorporated in the processing circuitry 41. The processor of the processing circuitry 41 implements various functions such as an acquisition function F1, an adjustment function F2, and a correction function F3.

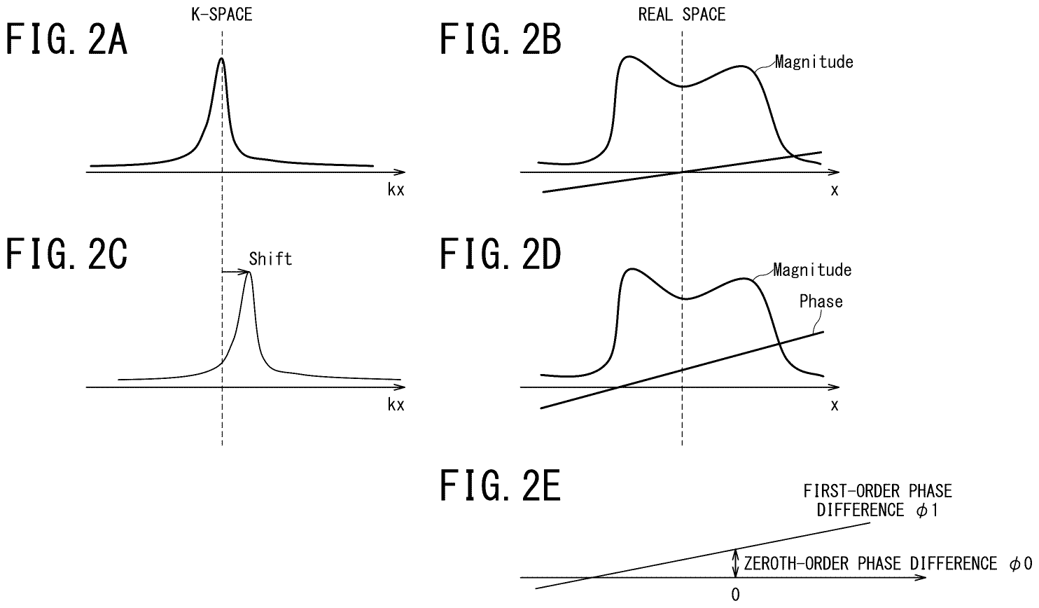

On the basis of FIG. 2A to FIG. 2E, the phase difference in a k-space and a real space will be described by comparing k-space data with real space data. FIG. 2B and FIG. 2D illustrate real space data obtained by performing one-dimensional Fourier transform on the MR signal data in the k-space of FIG. 2A and FIG. 2C, respectively. FIG. 2C shows the state in which the center of the echo in the k-space is shifted by a shift amount Shift of Expression 1 with respect to the case of FIG. 2A. The phase difference (or phase shift) in the real space is a phase difference that occurs between data acquired in a first readout direction and data acquired in a second readout direction opposite to the first readout direction due to influence of eddy currents and magnetic field non-uniformity, for example.

$$Shift = {n}_{x} \times \frac{{θ}_{1}}{2 π} \qquad Expression 1$$

In Expression 1, nₓ is the number of data sampling, and θ₁ is a phase coefficient corresponding to the first-order phase difference φ₁ in the real space.

FIG. 2E illustrates the zeroth-order phase difference and the first-order phase difference in the real space. On the basis of these zeroth-order phase difference and the first-order phase difference in the real space, the phase of the real space data can be corrected by inversely multiplying the linear phase shown in Expression 2, i.e., by multiplying the real space data by the complex conjugate of the linear phase shown in Expression 2. Furthermore, this correction processing can be performed after completion of data acquisition, and thus, neither adjustment of the phase difference before data acquisition nor acquisition of additional data for correction is required.

$$linear phase rotator = exp ( i ( {θ}_{1} x + {Φ}_{0} ) ) \qquad Expression 2$$

For example, in the EPI method in which the MRI apparatus acquires MR signal data to fill the k-space while reversing the polarity of the readout gradient magnetic field, the shift of echoes in the k-space between the plurality of MR signal data occurs due to eddy currents and magnetic field non-uniformity in the MRI apparatus. When phase encoding lines adjacent to each other in the k-space are sequentially filled with k-space data under the state where echo shifts are included in the k-space data, this becomes a factor causing N/2 artifacts in an MR image.

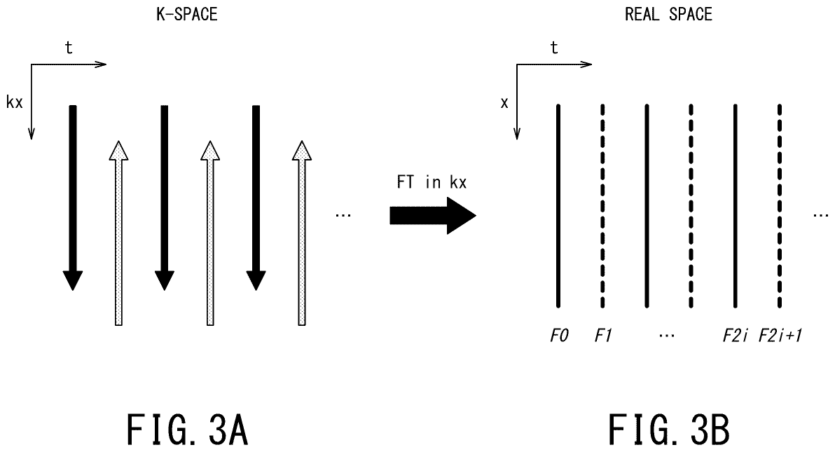

For this reason, in the known Ahn-Cho method, the zeroth-order phase correction and the first-order phase correction are performed to reduce the N/2 artifacts. The arrows indicating different directions in FIG. 3A schematically illustrate the filling trajectories of acquiring k-space data along the time axis while the polarity of the readout gradient pulse is being reversed repeatedly. FIG. 3B shows the real space data obtained by performing one-dimensional Fourier transform on the k-space data in FIG. 3A along the time axis. In the real space data in FIG. 3B, F2i(x) and F2i+1(x) represent data that are opposite to each other in polarity in the readout gradient pulse during acquisition.

For example, a phase coefficient θ₁ (φ1=θ1·x) corresponding to a first-order phase difference φ1 in the real space is calculated by using the real space data in the readout direction (i.e., the X-axis direction) as shown in Expression 3. A zeroth-order phase difference φ0 in the real space is estimated from the offset at the center position 0 in the real space after correction of the first-order phase difference.

$${θ}_{1} = angle [ {\sum }_{x} {\sum }_{i} {F}_{2 i} ( x ) \cdot conj ( {F}_{2 i + 1} ( x + 1 ) ) ] \qquad Expression 3$$

In Expression 3, the real space data F2i(x) represents the signal value (i.e., complex signal value) of the pixel that is the 2i-th in the time axis direction and is the x-th in the X-axis direction of the real space (FIG. 3B). In Expression 3, “conj(F)” represents the complex conjugate of the complex signal value F, and “angle[ ]” represents the operation of calculating the phase of the complex number in the square brackets [ ].

As shown in Expression 3, the phase coefficient θ1 corresponding to the first-order phase difference φ1 is obtained by calculating the phase of the correlation function of the signal values of pixels adjacent to each other in the time axis direction and the X-axis direction of the real space. In general, the imaging target region with larger signal values is often a region of interest that contains useful information for correction processing. However, when the signal value indicates a larger intensity in a region where the magnetic field uniformity is lower or where the phase changes abruptly, the phase correction may not be performed appropriately. Such inappropriate or unsuccessful phase correction may cause image degradation in the region of interest.

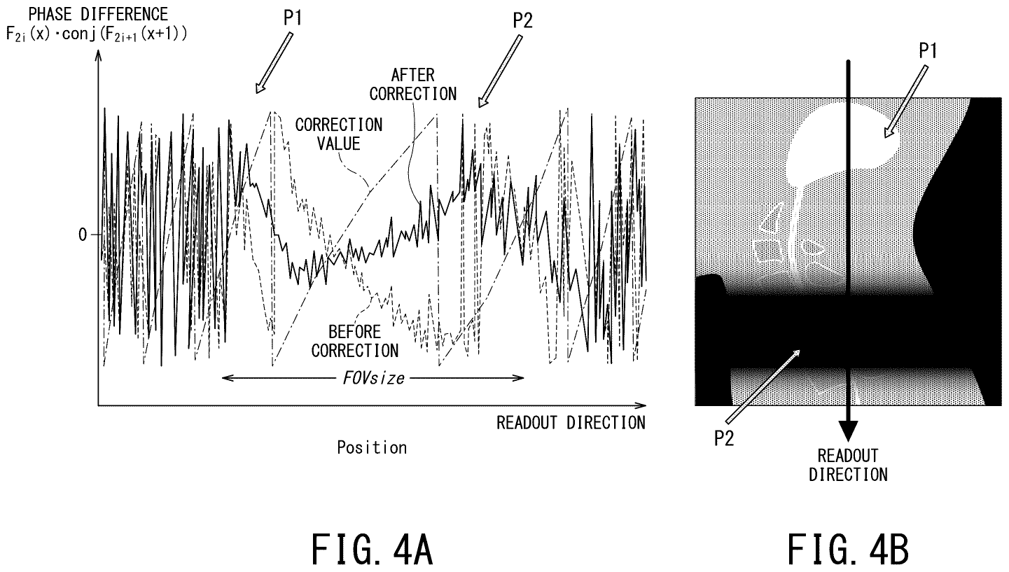

FIG. 4A and FIG. 4B are schematic diagrams illustrating unsuccessful phase correction in the region of interest. FIG. 4A shows the phase difference before correction (BEFORE CORRECTION), the correction amount (CORRECTION VALUE), and the phase difference after correction (AFTER CORRECTION) with respect to the readout direction. The phase difference after correction is the phase difference obtained by correcting the phase difference before correction with the use of the correction amount. FIG. 4B illustrates a generated image after the phase correction of FIG. 4A. When there is a locally larger signal value in the outer regions of the image where the magnetic field uniformity is lower as shown by position P1 in FIG. 4B, in some cases, the phase correction at position P2 in FIG. 4A is not performed appropriately due to the influence of the phase correction at the position P1. If the phase correction is not performed appropriately, image degradation such as shading may occur in the central region of the image with a relatively small signal value, as shown by the position P2 in FIG. 4B.

Thus, in the phase correction apparatus 4 according to the embodiment, in order to obtain an image in which the region of interest is satisfactorily depicted, the phase correction is performed to reduce the phase difference in the region of interest between data that are opposite to each other in polarity of the readout gradient pulse during acquisition.

### First Embodiment

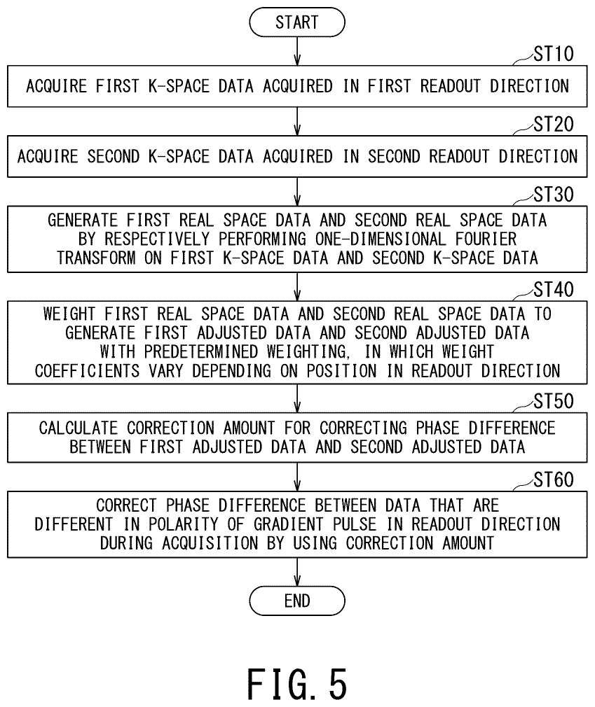

The processing circuitry 41 of the phase correction apparatus 4 includes an acquisition function F1, an adjustment function F2, and a correction function F3. The functions and operations of the processing circuitry 41 of the phase correction apparatus 4 will be described by referring to the flowchart of FIG. 5 and FIG. 6 to FIG. 10B.

In the step ST10, the acquisition function F1 acquires first k-space data that are acquired in the first readout direction. The acquisition function F1 may acquire one first k-space data or a plurality of first k-space data. The first k-space data may be acquired via the network interface 44 or from the memory 42.

In the step ST20, the acquisition function F1 acquires second k-space data that are acquired in the second readout direction. The acquisition function F1 may acquire one second k-space data or a plurality of second k-space data. The second k-space data may be acquired via the network interface 44 or from the memory 42.

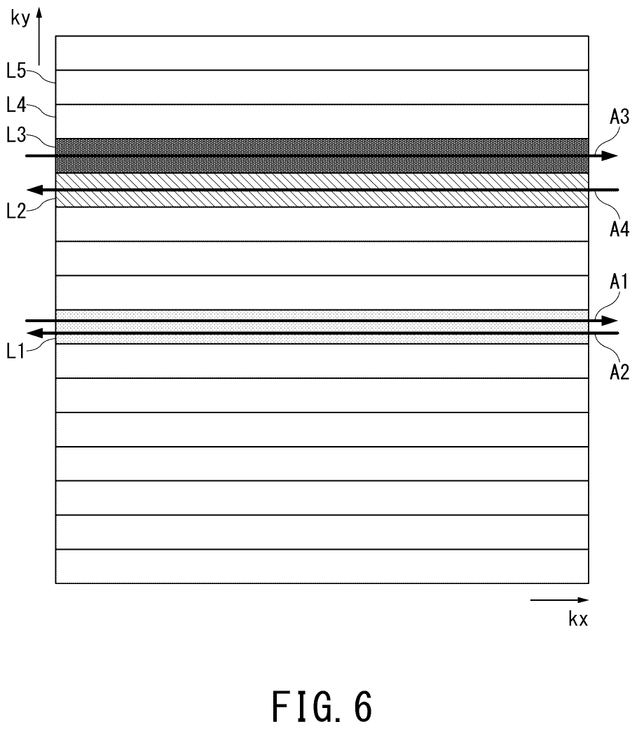

The readout direction of each of the first k-space data and the second k-space data will be described by using FIG. 6. It is preferred that the first k-space data and the second k-space data are at least one pair of data to be filled in the same k-space phase encoding line, that are opposite to each other in polarity of the readout gradient pulse during acquisition. The first k-space data and the second k-space data may be at least one pair of data that are filled in the same k-space phase encoding line L1 and is filled in the direction of the arrow A1 and the direction of the arrow A2 opposite to the arrow A1. Although the k-space phase encoding line with the zero phase in the ky direction is shown as the same k-space phase encoding line L1 in FIG. 6, the same k-space phase encoding line does not have to be zero phase in the ky direction, for example, such as the k-space phase encoding line L2.

The first k-space data and the second k-space data may be at least one pair of data that are filled in k-space phase encoding lines adjacent to each other. The first k-space data and the second k-space data may be at least one pair of data that are filled in the k-space phase encoding lines L3 and L2 adjacent to each other in the ky direction and is acquired in the direction of the arrow A3 and the direction of the arrow A4 opposite to the arrow A3, respectively. The k-space phase encoding lines adjacent to each other are not limited to k-space phase encoding lines L3 and L2 but may be other adjacent k-space phase encoding lines.

It is sufficient that the first k-space data and the second k-space data are at least one pair of data that are opposite to each other in polarity of the readout gradient pulse during acquisition, and do not have to be data from the k-space phase encoding lines adjacent to each other or data from the same k-space phase encoding line.

The plurality of first k-space data and the plurality of second k-space data are a plurality of data to be acquired along the time axis as shown in FIG. 3A. The plurality of first k-space data and the plurality of second k-space data may be a plurality pairs of data, that are filled in the same k-space phase encoding line and opposite to each other in polarity of the readout gradient pulse during acquisition.

The plurality of first k-space data and the plurality of second k-space data may be plural pairs of data that are filled in k-space phase encoding lines adjacent to each other. In such a case, the plurality of first k-space data and the plurality of second k-space data may be plurality pairs of data that are filled in a pair of k-space phase encoding lines adjacent to each other, such as the k-space phase encoding lines L2 and L3 in FIG. 6, or may be data that are filled in two or more pairs of k-space phase encoding lines adjacent to each other, such as the pair of k-space phase encoding lines L2 and L3 and the pair of k-space phase encoding lines L4 and L5 in FIG. 6.

In addition, the plurality of first k-space data and the plurality of second k-space data may be composed of a combination of at least one pair of data filled in the same k-space phase encoding line and at least one pair of data filled in k-space phase encoding lines adjacent to each other.

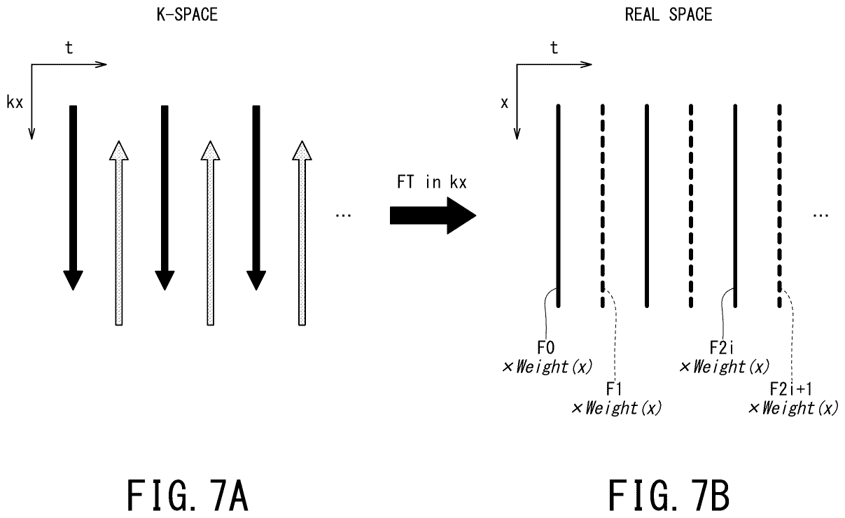

In the step ST30, the adjustment function F2 generates first real space data and second real space data by performing one-dimensional Fourier transform on the first k-space data and the second k-space data, respectively. FIG. 7A is the same as FIG. 3A that shows data acquisition in which the polarity of the readout gradient pulse is alternately inversed along the time axis. FIG. 7B illustrates the real space data along the time axis obtained by performing one-dimensional Fourier transform on the k-space data shown in FIG. 7A.

In the step ST40, the adjustment function F2 weights the first real space data to generate the first adjusted data with a predetermined weighting in which weight coefficients vary depending on the pixel position in the readout direction, and weights the second real space data to generate the second real space data with such a predetermined weighting.

When the plurality of first k-space data and the plurality of second k-space data are acquired, the adjustment function F2 may generate a plurality of first adjusted data and a plurality of second adjusted data on the basis of a plurality of first real space data and a plurality of second real space data obtained by performing one-dimensional Fourier transform on the plurality of first k-space data and the plurality of second k-space data, respectively. In detail, the plurality of first adjusted data are obtained by weighting the plurality of first real space data with a predetermined weighting in which weight coefficients vary depending on the pixel position in the readout direction, and the plurality of second adjusted data are obtained by weighting the plurality of second real space data with such a predetermined weighting.

FIG. 7B differs from FIG. 3B in terms of generating the first adjusted data and the second adjusted data by respectively weighting the first real space data and the second real space data with a predetermined weighting Weight(x) in which weight coefficients vary depending on the pixel position in the X-axis direction, i.e., the readout direction. As shown in Expression 4, the adjusted data G(x) are obtained from the real space data F(x) and the predetermined weighting Weight(x). In the real space data in FIG. 7B, F2i(x) and F2i+1(x) represent data that are opposite to each other in polarity of the readout gradient pulse during acquisition.

$$G ( x ) = F ( x ) \cdot Weight ( x ) \qquad Expression 4$$

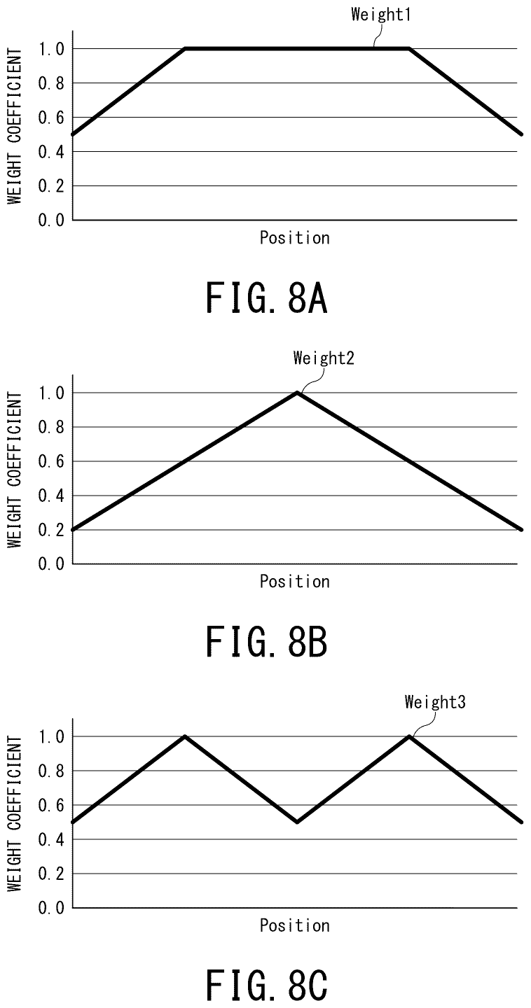

The predetermined weighting depending on the pixel position in the readout direction to be used by the phase correction apparatus 4 will be described by referring to FIG. 8A to FIG. 10B. The shape of the predetermined weighting Weight(x) is given depending on the pixel position in the readout direction in the image. The larger the weight coefficient is, the larger it is as a factor in the phase correction. In other words, the correction effect is larger at a pixel position with a larger predetermined weighting Weight(x). Thus, it is preferred to optimize and set the predetermined weighting Weight(x) in such a manner that the weighting in the region of interest where image quality is prioritized is set larger than other regions in the entire imaging region.

FIG. 8A, FIG. 8B, and FIG. 8C illustrate aspects of the predetermined weighting Weight(x) and respectively illustrate a first weighting aspect Weight1, a second weighting aspect Weight2, and a third weighting aspect Weight3. As shown in the first weighting aspect Weight1 in FIG. 8A and the second weighting aspect Weight2 in FIG. 8B, the predetermined weighting Weight(x) may be weighting that gives a higher weight coefficient to the central region in the pixel position in the readout direction than the outer regions outside the central region.

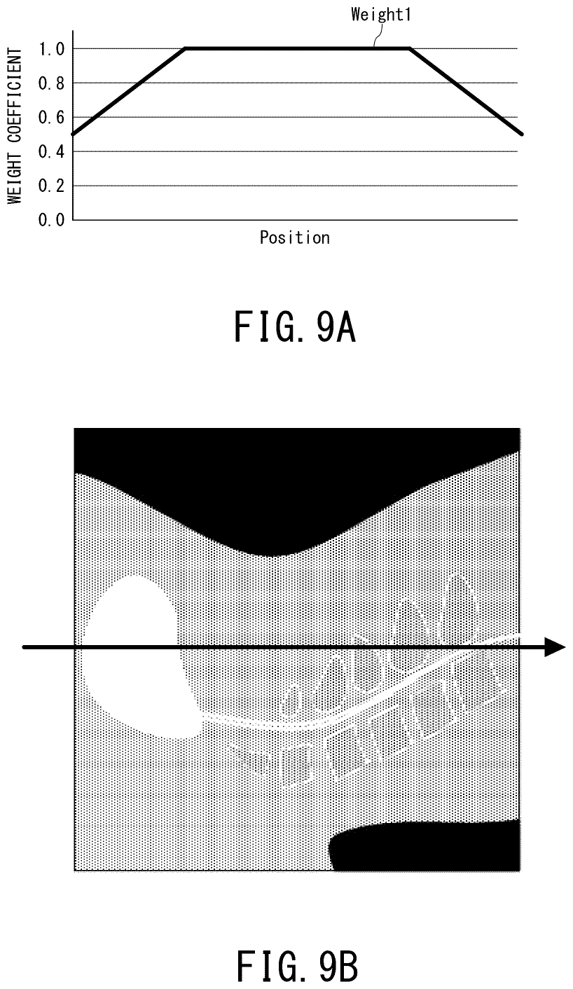

FIG. 9A is the same as FIG. 8A, and FIG. 9B shows one case where the first weighting aspect Weight1 in FIG. 9A is applied. For example, when the central region of the imaging region is the region of interest and the image quality of the central region is prioritized or emphasized such as the spine image in FIG. 9B, it is preferred to set the weighting in such a manner that the phase of the central region of the image is corrected.

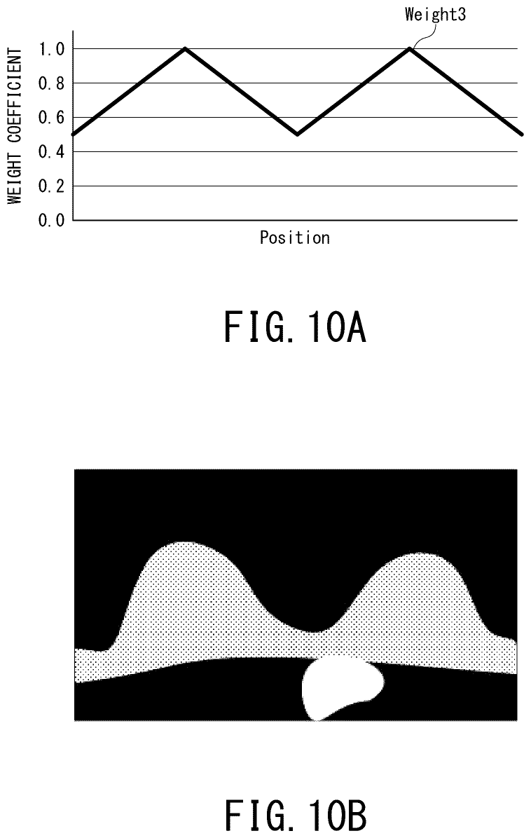

FIG. 10A is the same as FIG. 8B, and FIG. 10B shows one case where the second weighting aspect Weight2 in FIG. 10A is applied. The second weighting aspect Weight2 is a two-peaked weighting. When the region of interest is separated into two or more subregions within the imaging region like the chest image in FIG. 10B, it is preferred to set the weighting in such a manner that the phase correction is performed for each subregion in the region of interest.

As shown in FIG. 9A and FIG. 10A, the predetermined weighting is desirably a weighting that gives a higher weight coefficient to the region of interest than to a region of non-interest. It may be configured such that a user acquires information on a designated region of interest and the predetermined weighting is set on the basis of the information on the region of interest. The information on the region of interest is information on a region to be weighted higher and/or information on a region to be weighted lower, for example. Regions that can be designated regarding the information on the region of interest are not limited to a two-dimensional or three-dimensional region but may be a point or a line, and is not limited to one but may be plural. The information on the region of interest is obtained via the input interface 43.

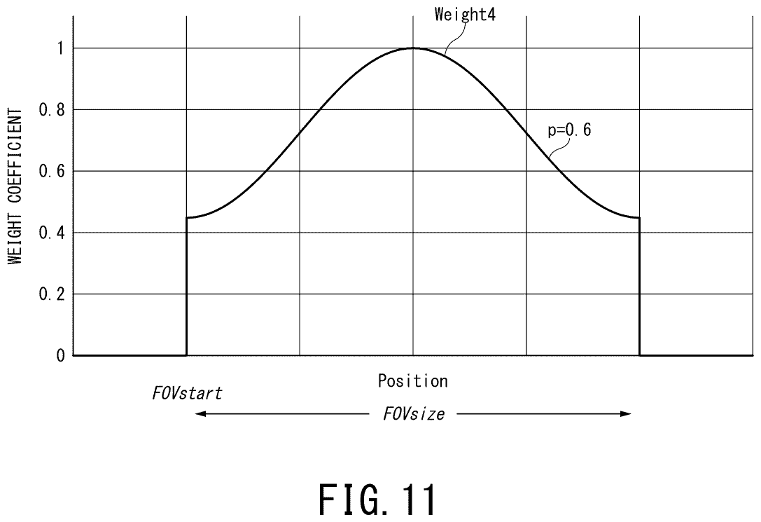

FIG. 11 shows a fourth weighting aspect Weight4. The fourth weighting aspect Weight4 in FIG. 11 is the weighting according to Expression 5 when p=0.6 and q=0. In this manner, the predetermined weighting may be a weighting based on a Hamming window function in which the center positions in the readout direction for acquiring the first k-space data and the second k-space data constitute the line-symmetric axis. The Hamming window function is a window function that does not set both ends of the imaging region, i.e., FOV (Field Of View), as 0. Thus, when the Hamming window function is set as the predetermined weighting for the FOV, the weight coefficients will never become zero inside the FOV. In other words, the spatial distribution information of hydrogen atom density represented by MR signal intensity will never be zero at any position in the imaging region.

The predetermined weighting may be set such that pixel values in regions outside the FOV after inverse Fourier transform are changed to predetermined values such as zero and a value close to zero. The region outside the FOV, which is not a region of interest, is not necessary to be subjected to the phase-difference correction.

$$Weight ( x ) = \{ \begin{matrix}q , x < FOV start , x > FOV start + FOV size \\ 1 + p [ 0.54 - 0.46 cos ( 2 π \frac{x - FOV start}{FOV size} ) - 1 ] , FOV start , \leq x \leq FOV start + FOV size\end{matrix} \qquad Expression 5$$

In Expression 5, p and q are any variables between 0 and 1.

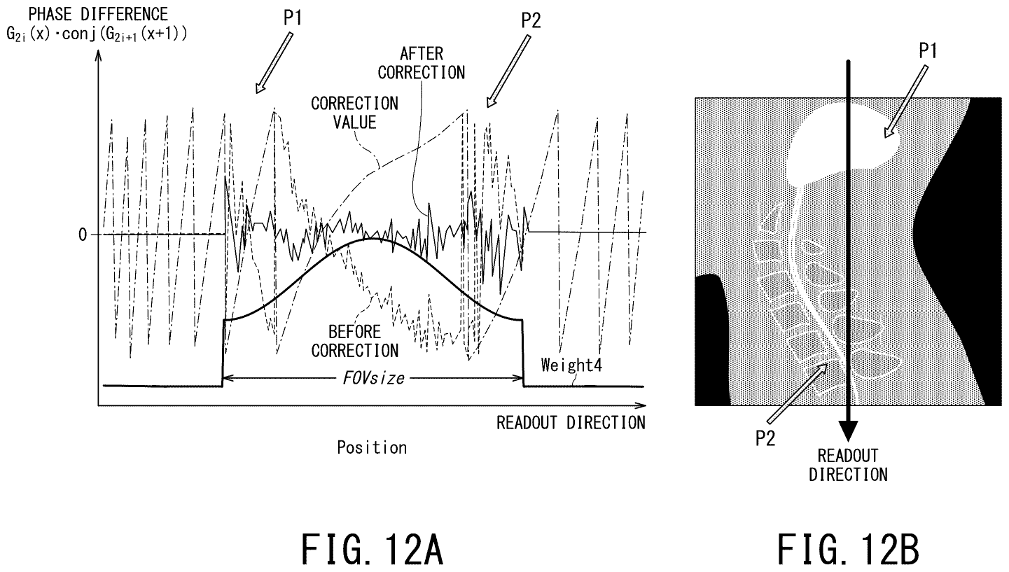

FIG. 12A and FIG. 12B are schematic diagrams illustrating one case of the phase correction by the fourth weighting aspect Weight4. FIG. 12A shows the phase difference before correction (BEFORE CORRECTION), the correction amount (CORRECTION VALUE), and the phase difference after correction (AFTER CORRECTION) with respect to the readout direction. The phase difference after correction is a value obtained by correcting the phase difference before correction with the use of the correction amount. FIG. 12B illustrates the image generated after the phase correction of FIG. 12A. In FIG. 12A, positions P1 and P2 are in the outer regions of the image and are lower in magnetic field uniformity, thus, the variance of the phase difference tends to be larger than that of the central region.

Hence, in order to make the correction amount of the phase difference less susceptible to the influence of the variance of the phase difference, the predetermined weighting is desirably set such that the weight coefficients are lower in the region where the variance of the phase difference is larger than the predetermined variance. By such a weighting, as shown by the position P1 in FIG. 12B, even if the magnetic field uniformity is lower and there is a locally larger signal value of pixels in the outer regions of the image where the variance of the phase difference between the first real space data and the second real space data is larger than the predetermined variance, the phase correction at the position P2 in FIG. 12A can be performed appropriately without being influenced by the phase correction at the position P1, and the image quality in the central region of the image, i.e., the region of interest, is also satisfactorily maintained. The predetermined weighting may be set such that weight coefficients are higher in the region of interest and are lower in regions where the variance of the phase difference is larger.

In addition, also when the plurality of first k-space data and the plurality of second k-space data are acquired, the predetermined weighting is desirably set such that weight coefficients are lower in the region where the variance of the phase difference is larger than the predetermined variance.

In the step ST50, the correction function F3 calculates the correction amount for correcting the phase difference between the first adjusted data and the second adjusted data.

For example, the phase coefficient θ1 corresponding to the first-order phase difference φ1 in the real space is calculated by using the adjusted data weighted with the predetermined weighting in which weight coefficients vary depending on the pixel position in the readout direction, as shown in Expression 6. The zeroth-order phase difference φ0 in the real space is estimated from the offset at the center position 0 after correction of the first-order phase difference.

$${θ}_{1} = angle [ {\sum }_{x} {\sum }_{i} {G}_{2 i} ( x ) \cdot conj ( {G}_{2 i + 1} ( x + 1 ) ) ] \qquad Expression 6$$

In Expression 6, the adjusted data G2i(x) represents the signal value (i.e., complex signal value) of the 2i-th pixel in the time axis direction and the x-th pixel in the X-axis direction of the real space. As shown in Expression 6, the phase coefficient θ1 corresponding to the first-order phase difference φ1 is obtained by calculating the phase of the correlation function of the respective signal values of pixels adjacent to each other in the time axis direction and in the X-axis direction of the real space.

In the step ST60, on the basis of the correction amount, the correction function F3 corrects the phase difference between data that are opposite to each other in polarity of the readout gradient pulse during acquisition.

Although a description has been given of the phase coefficient θ1 corresponding to the first-order phase difference φ1 in the real space, the phase correction apparatus 4 can correct higher-order phase differences in the real space, such as second-order, third-order, and fourth-order phase differences, as shown in FIG. 12A where the correction amount is shown as a curve rather than a straight line, for example.

When the plurality of first k-space data and the plurality of second k-space data are acquired, the correction function F3 calculates a plurality of correction amounts for correcting the phase differences between the plurality of first adjusted data and the plurality of second adjusted data, and corrects the phase differences between the plurality of data that are opposite to each other in polarity of the readout gradient pulse during acquisition, by using these correction amounts.

For example, the correction may be performed so as to minimize the sum of the phase differences after the correction by calculating the correction amount for each of: the set of the first adjusted data G0 and the second adjusted data G1; the set of the first adjusted data G2 and the second adjusted data G3; the set of the first adjusted data G2i and the second adjusted data G2i+1; and so on.

According to the phase correction method and the phase correction apparatus 4 of the first embodiment, the phase correction can be performed to reduce the phase difference in the region of interest between data that are opposite to each other in polarity of the readout gradient pulse during acquisition. Even in the case of EPI in which MR signals are acquired by alternately inverting the polarity of the readout gradient pulse and the k-space is filled with digitized data of the MR signals, the phase correction is stably performed and degradation in terms of image quality in the region of interest can be reduced.

### Second Embodiment

The phase correction apparatus 4 according to the second embodiment differs from the phase correction apparatus 4 according to the first embodiment in that the predetermined weighting is selected from a plurality of types of weighting. The phase correction apparatus 4 according to the second embodiment does not substantially differ from the phase correction apparatus 4 according to the first embodiment in configuration, function, and operation of other points, and duplicate descriptions are omitted.

In the second embodiment, in the step ST40 of FIG. 5, the adjustment function F2 acquires a plurality of types of weighting and selects one predetermined weighting from among the acquired plurality of types of weighting. For example, the correction amount is calculated for each of the plurality of weightings, and one predetermined weighting is selected on the basis of the corrected phase difference to which the correction amount is applied.

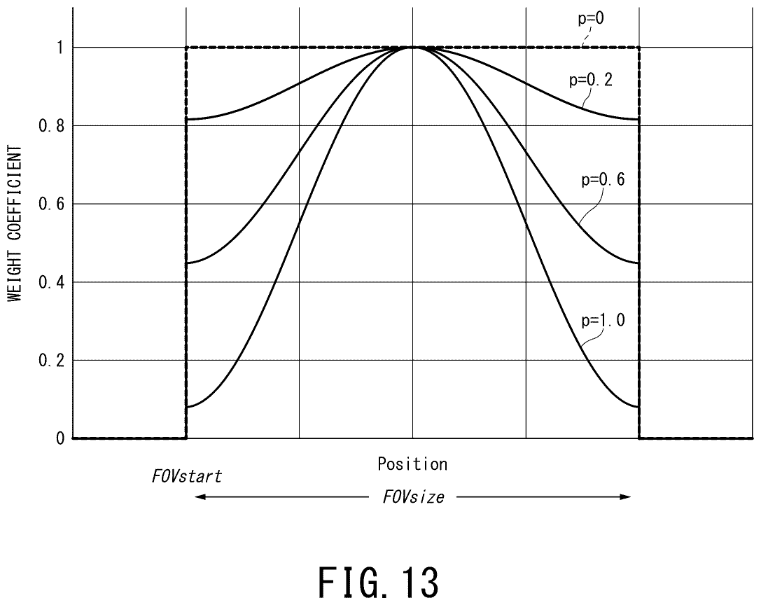

FIG. 13 shows four weightings using the Hamming window function of Expression 4 under the condition of q=0, where p is changed in four ways: p=0, p=0.2, p=0.6, and p=1.0. As shown in FIG. 13, the plurality of types of weighting Weight(x) can be obtained by changing the value of p. Among the plurality of types of weightings, the predetermined weighting is set to the weighting that minimizes the sum of the phase differences between data that are opposite to each other in polarity of the readout gradient pulse during acquisition. For example, the sum of the corrected phase differences is obtained by applying correction evaluation Metric of Expression 7 to the corrected phase differences subjected to the plurality of types of weighting. The weighting that minimizes the sum of the phase differences after this correction may be selected as the predetermined weighting from the plurality of types of weighting.

$$Metric = {\sum }_{x} {\sum }_{i} [ \{ \vert {G}_{2 i} ( x ) \cdot con j ( {G}_{2 i + 1} ( x + 1 ) ) \vert \cdot conj \vert angle ( {G}_{2 i} ( x ) \cdot conj ( {G}_{2 i + 1} ( x + 1 ) ) ) \vert ] \qquad Expression 7$$

As to acquiring the plurality of types of weighting, in addition to the approach of varying at least one variable in one arithmetic expression, the plurality of types of weighting may be obtained from a plurality of arithmetic expressions, from a data table related to the plurality of types of weighting, or obtained from both the data table and one or plural arithmetic expressions. At least one of the data table and one or more arithmetic expressions for generating the plurality of types of weighting are stored in the memory 42, for example.

According to the phase correction method and the phase correction apparatus 4 of the second embodiment, the same effects as those of the phase correction method and the phase correction apparatus 4 of the first embodiment can be obtained. Since the optimal or appropriate predetermined weighting can be selected from the plurality of types of weighting by correction evaluation or other evaluation method for evaluating the error of the phase correction in the case of applying the weighting, stabler phase correction than the first embodiment is available.

### (Overall Configuration of MRI Apparatus)

An MRI apparatus 1 according to the embodiment is provided with the phase correction apparatus 4. The phase correction device 4 incorporated in the main body of MRI apparatus 1, or the phase correction apparatus 4 may be installed in a remote room and communicate with the MRI apparatus 1 via network. The MRI apparatus 1 is capable of applying MRI techniques.

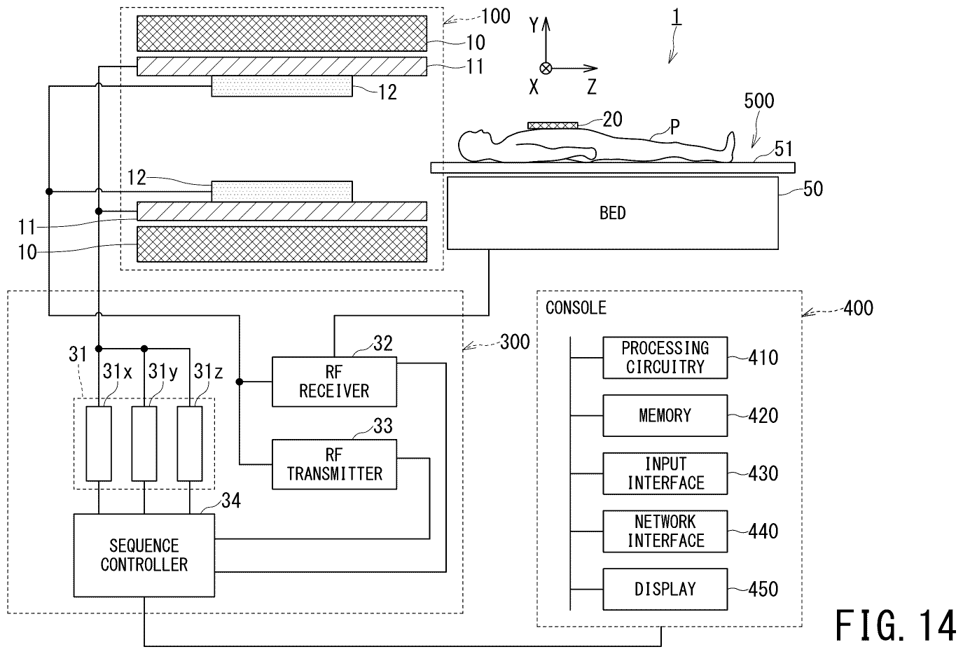

FIG. 14 is a block diagram illustrating an overall configuration of the MRI apparatus 1 according to the embodiment. The MRI apparatus 1 includes a gantry 100, a control cabinet 300, an image processing device 400 such as a console, and a bed 500.

The gantry 100 and the bed 500 are disposed in a shielded room called an examination room, for example. The control cabinet 300 is disposed in a machine room and the image processing device 400 is disposed in a control room, for example. The image processing device 400 may be installed in a remote location away from the control room and be connected to the MRI apparatus 1 via the network.

The gantry 100 includes a static magnetic field magnet 10, a gradient coil 11, and a WB (Whole Body) coil 12. The static magnetic field magnet 10 of the gantry 100 is broadly classified into a cylindrical type in which the magnet has a cylindrical structure and an open type in which a pair of magnets are arranged above and below an imaging space interposed therebetween. Although a description will be given of a case where the gantry 100 of the MRI apparatus 1 is cylindrical, the gantry 100 of the MRI apparatus 1 may be configured as the open type. The open type MRI apparatus has the same configuration as the cylindrical MRI apparatus 1 except that each of the static magnetic field magnets, the gradient coil, and the WB coil constituting the gantry are formed into a pair of tabular structures in parallel with each other.

The static magnetic field magnet 10 is substantially in the form of a cylinder and generates a static magnetic field inside a bore into which an object P is moved. The bore is a space inside the cylindrical structure of the gantry 100. The static magnetic field magnet 10 is composed of a housing for holding liquid helium, a refrigerator for cooling down the liquid helium to an extremely low temperature, and a superconducting coil inside the housing, for example. Note that the static magnetic field magnet 10 may be configured as a permanent magnet. Hereinafter, a description will be given of a case where the static magnetic field magnet 10 has the superconducting coil.

The static magnetic field magnet 10 includes the superconducting coil inside, and the superconducting coil is cooled down to an extremely low temperature by the liquid helium. The static magnetic field magnet 10 generates a static magnetic field by supplying the superconducting coil with an electric current provided from a static magnetic field power supply (not shown) in an excitation mode. Afterward, when the static magnetic field magnet 10 shifts to a persistent current mode, the static magnetic field power supply is disconnected. Once it enters the persistent current mode, the static magnetic field magnet 10 continues to generate a strong static magnetic field for a long time, for example, over one year.

The gradient coil 11 is also substantially in the form of a cylinder similarly to the static magnetic field magnet 10, and is fixed to the inside of the static magnetic field magnet 10. To be exact, the gradient coil 11 is a gradient coil assembly that is composed of three gradient coils for the respective X-axis, Y-axis, and Z-axis. These three gradient coils generate and apply gradient magnetic fields to the object P in the respective directions of the X-axis, the Y-axis, and the Z-axis by using gradient-magnetic-field currents (i.e., electric power) supplied from respective gradient-coil power supplies 31x, 31y, and 31z of a gradient coil power supply unit 31 described below. The Z-axis direction is a direction along the static magnetic field, the Y-axis direction is along the gravity direction, and the X-axis direction is the direction perpendicular to both the Z-axis and the Y-axis.

The WB coil 12 is shaped substantially in the form of a cylinder so as to surround the object P and is installed inside the gradient coil 11. The WB coil 12 functions as a transmitting coil. In other words, the WB coil 12 applies an RF pulse based on the RF signal transmitted from an RF transmitter 32 to the object P. In some cases, the WB coil 12 has a function as a receiving coil in addition to the function as a transmitting coil that transmits RF pulses. In this case, the WB coil 12 serves as a receiving coil that receives MR signals emitted from the object P due to the excitation of the atomic nuclei.

The MRI apparatus 1 may include a local coil 20 in addition to the WB coil 12. The local coil 20 is disposed close to the body surface of the object P. The local coil 20 may include a plurality of coil elements. There are various models of the local coil 20 such as a head coil, a chest coil, an abdomen coil, a spine coil, and a knee coil. Although FIG. 1 illustrates a case where the local coil 20 is the chest coil, embodiments are not limited to such an aspect.

The local coil 20 functions as a receiving coil, i.e., receives the above-described MR signals. The local coil 20 may be a transmitting/receiving coil that has both the function to transmit RF pulses as a transmitting coil and the function to receive MR signals as a receiving coil. In other words, the local coil 20 can be used for transmission only, for reception only, or for both transmission and reception.

The bed 500 includes a bed body 50 and a table 51. The bed body 50 can move the table 51 in the vertical direction and in the horizontal direction, and moves the table 51 with the object P placed thereon to a predetermined height before imaging. Afterward, the bed body 50 moves the table 51 in the horizontal direction so as to move the object P to the inside of the bore.

The control cabinet 300 includes: the gradient coil power supply unit 31 composed of the X-axis gradient coil power supply 31x, the Y-axis gradient coil power supply 31y, and the Z-axis gradient coil power supply 31z; the RF transmitter 32; an RF receiver 33; and a sequence controller 34.

The gradient coil power supply unit 31 includes the gradient coil power supplies 31x, 31y, 31z, which are for respective channels and drive the respective gradient coils configured to generate the gradient magnetic fields in the respective X-axis, Y-axis, and Z-axis directions. The gradient coil power supplies 31x, 31y, 31z output necessary electric currents independently for each channel on the basis of instructions from the sequence controller 34

The RF transmitter 32 generates RF signals on the basis of instructions from the sequence controller 34. The RF transmitter 32 transmits the generated RF signals to the WB coil 12 and/or the local coil 20.

The MR signals received by the WB coil 12 and/or the local coil 20 are transmitted to the RF receiver 33. The RF receiver 33 performs analog-to-digital (A/D) conversion of the MR signals acquired from the WB coil 12 and/or the local coil 20, and outputs the digitized MR signals to the sequence controller 34. Data of the digitized MR signals are sometimes referred to as raw data.

The sequence controller 34 performs a scan of the object P by driving the gradient coil power supply unit 31, the RF transmitter 32, and the RF receiver 33 under the control of the image processing device 400. When the sequence controller 34 receives the raw data acquired by the scan from the RF receiver 33, the sequence controller 34 transmits the raw data to the image processing device 400.

The sequence controller 34 includes processing circuitry (not shown). This processing circuitry is composed of, for example, a processor configured to execute predetermined programs and/or hardware such as an FPGA (Field Programmable Gate Array) and an ASIC (Application Specific Integrated Circuit).

Next, the image processing device 400 will be described. The image processing device 400 includes processing circuitry 410, a memory 420, an input interface 430, and a display 450. The image processing device 400 may further include a network interface 440.

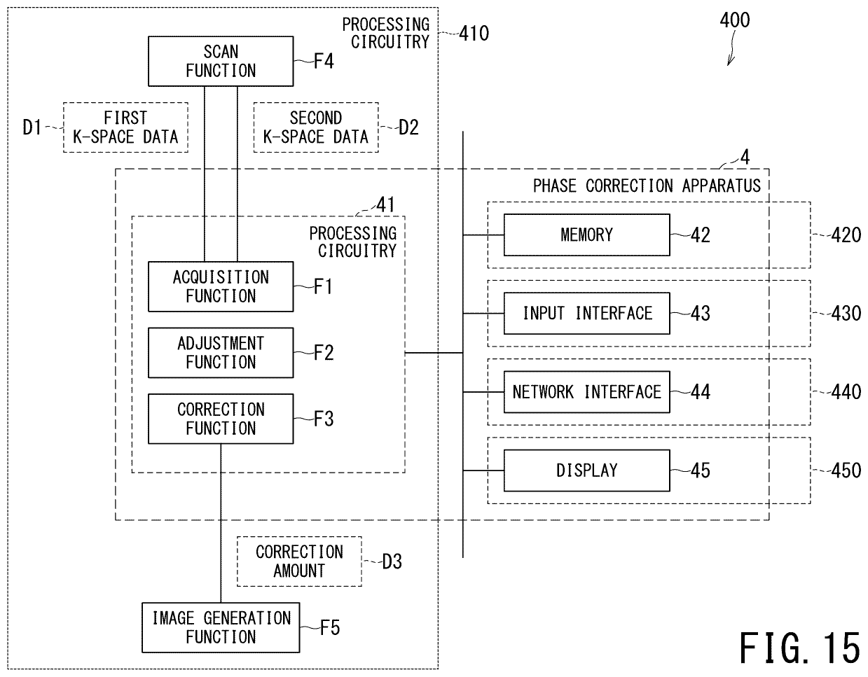

FIG. 15 is a block diagram illustrating a configuration of the MRI apparatus 1 that includes the phase correction apparatus 4 according to the embodiment.

The display 450 has the configuration of the display 45 of the phase correction apparatus 4, and duplicate descriptions are omitted. The display 450 further displays various information items under the control of the processing circuitry 410.

The network interface 440 has the configuration of the network interface 44 of the phase correction apparatus 4, and duplicate descriptions are omitted. The network interface 440 can exchange various data such as MR signal data of the object between the network and the memory 420, for example.

The input interface 430 has the configuration of the input interface 43 of the phase correction apparatus 4, and duplicate descriptions are omitted.

The memory 420 has the configuration of the memory 42 of the phase correction apparatus 4, and duplicate descriptions are omitted. The memory 420 further stores various processing programs to be executed by the processing circuitry 410, data necessary for executing the programs, and medical images.

As described above, the processing circuitry 41 realizes the function of integrally controlling the phase correction apparatus 4. The processing circuitry 41 is a processor that implements various functions by reading out and executing various processing programs stored in the memory 42 or directly incorporated in the processing circuitry 41. The processor of the processing circuitry 41 implements respective functions such as the acquisition function F1, the adjustment function F2, and the correction function F3.

The processing circuitry 410 of the MRI apparatus 1 has the configuration of the processing circuitry 41 of the phase correction apparatus 4, and duplicate descriptions are omitted. Further, the processing circuitry 410 is a processor that implements various functions by reading out and executing various processing programs stored in the memory 420 or directly incorporated in the processing circuitry 410. The image processing device 400 controls the entirety of the MRI apparatus 1 by using these components.

Specifically, the processing circuitry 410 receives various information items including imaging conditions and instructions via operations on the input interface 430, such as a mouse and a keyboard, to be performed by a user such as a medical imaging technologist. The processing circuitry 410 causes the sequence controller 34 to execute a scan on the basis of the inputted imaging conditions and the pulse sequences such as a pulse sequence of the EPI method, and reconstructs MR images on the basis of the data transmitted from the sequence controller 34. The reconstructed MR images are displayed on the display 450 and stored in the memory 420.

The processing circuitry 410 includes the processing circuitry 41 of the phase correction apparatus 4, and implements the acquisition function F1, the adjustment function F2, and the correction function F3. Regarding the detailed functions and operations to be achieved by the acquisition function F1, the adjustment function F2, and the correction function F3, duplicate descriptions are omitted. The processing circuitry 410 of the MRI apparatus 1 differs from the processing circuitry 41 of the phase correction apparatus 4 in that the processing circuitry 410 further implements a scan function F4 and an image generation function F5.

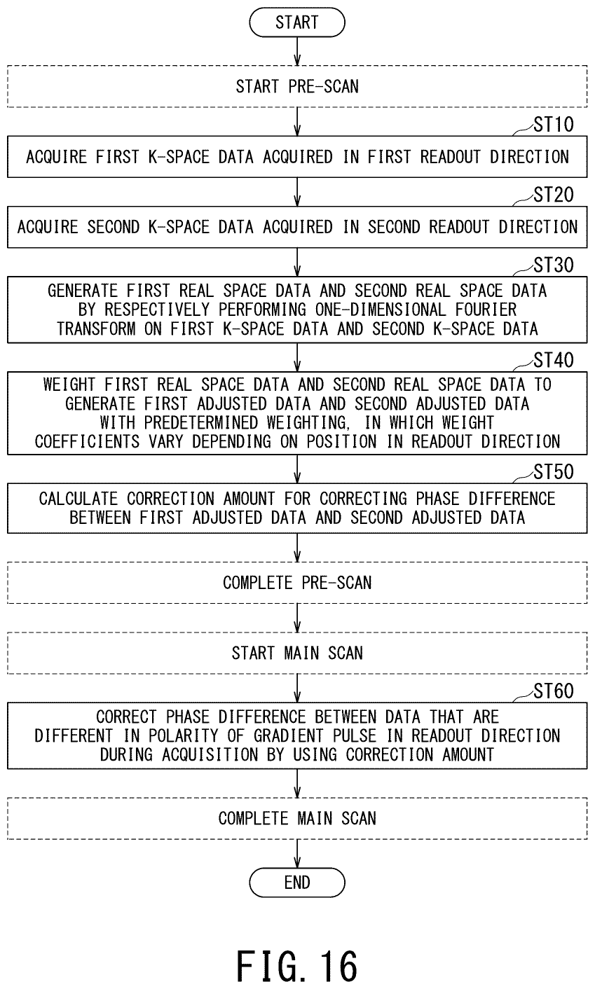

FIG. 16 is a flowchart illustrating a first operation to be performed by the MRI apparatus 1 according to the embodiment. In the first operation, a pre-scan is started before the step ST10. A pre-scan is a calibration scan to be performed before a main scan for acquiring MR signals necessary for reconstructing at least one MR image. In the first operation, the steps ST10, ST20, ST30, ST40, and ST50 are performed during the pre-scan so as to calculate the correction amount. In other words, the first k-space data and the second k-space data are acquired during the pre-scan of MRI. The scan function F4 acquires the first k-space data and the second k-space data.

After the step ST50, the main scan begins. The scan function F4 acquires MR-image data for generating MR images during the main scan. The image generation function F5 generates MR images from the MR-image data that are corrected on the basis of the correction amount calculated in the step ST50. In the first operation, the correction amount is calculated from the first k-space data and the second k-space data that are acquired in the pre-scan, and then the phase correction of the MR-image data acquired in the main scan is performed.

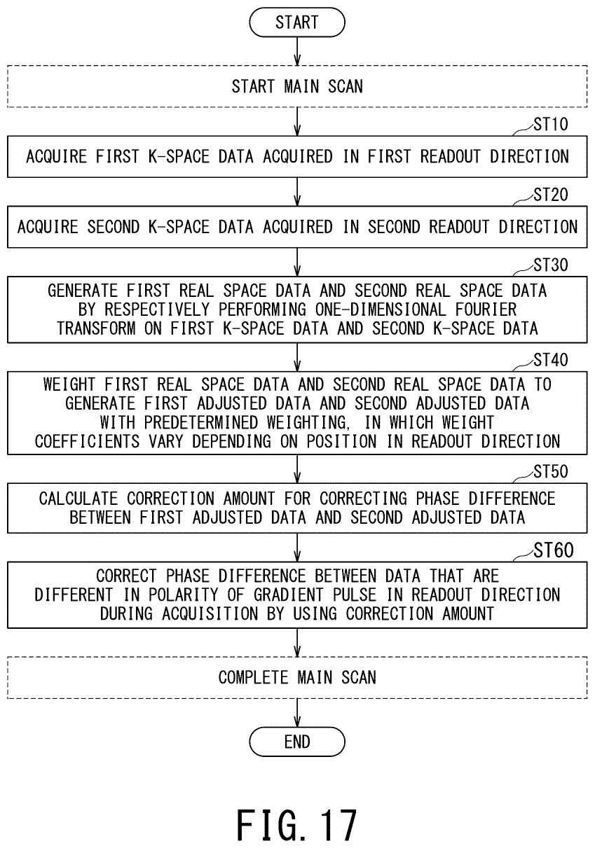

FIG. 17 is a flowchart illustrating a second operation to be performed by the MRI apparatus 1 according to the embodiment. In the second operation, the main scan begins before the step ST10. In the second operation, the processing of the steps ST10, ST20, ST30, ST40, and ST50 is performed during the main scan to calculate the correction amount. In other words, the first k-space data and the second k-space data are acquired during the main scan of MRI. The scan function F4 acquires the first k-space data and the second k-space data.

The scan function F4 also acquires the MR-image data for generating MR images during the main scan. The image generation function F5 generates MR images from the MR-image data that are corrected on the basis of the correction amount calculated in the step ST50. In the second operation, the correction amount is calculated from the first k-space data and the second k-space data that are acquired in the main scan, and the phase correction of the MR-image data acquired in the main scan is performed.

According to the phase correction method, the phase correction apparatus, and the MRI apparatus of at least one embodiment describe above, the phase correction can be performed to reduce the phase difference in the region of interest between data that are opposite to each other in polarity of the readout gradient pulse during acquisition.

In the above-described embodiments, the term “processor” means a circuit such as a special-purpose or general-purpose CPU (Central Processing Unit), a GPU (Graphics Processing Unit), an ASIC, a programmable logic device including an SPLD (Simple Programmable Logic Device) and a CPLD (Complex Programmable Logic Device), and an FPGA, for example.

For example, when the processor is a CPU, the processor implements various functions by reading out and executing programs stored in the memory. For example, when the processor is an ASIC, instead of storing the programs in the memory, the functions corresponding to the programs are directly incorporated into the circuit of the processor as a logic circuit. In this case, the processor implements various functions by hardware processing of reading out and executing the programs stored in the circuit. Additionally or alternatively, the processor can realize various functions by combining software processing and hardware processing.

Although a description has been given of the case where the single processor of the processing circuitry realizes the respective functions in the above-described embodiments, the processing circuitry may be configured by combining a plurality of independent processors in such a manner that each processor implements each function. Further, when a plurality of processors are provided, a memory for storing the programs may be individually provided for each processor or a single memory may collectively store the programs corresponding to the functions of all the processors.

While certain embodiments have been described, these embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the scope of the invention as defined by the appended claims.

What is claimed is:

1. A phase correction method comprising:
acquiring first k-space data acquired in a first readout direction and second k-space data acquired in a second readout direction that is opposite to the first readout direction;
weighting first real space data to generate first adjusted data with a predetermined weighting, wherein weight coefficients in the predetermined weighting vary depending on a pixel position in a readout direction and become lower in a region where a variance of a phase difference is larger than a predetermined variance, the first real space data being obtained by performing one-dimensional Fourier transform on the first k-space data;
weighting second real space data to generate second adjusted data with the predetermined weighting, the second real space data being obtained by performing one-dimensional Fourier transform on the second k-space data;
calculating a correction amount for correcting a phase difference between the first adjusted data and the second adjusted data; and
correcting a phase difference between data that are different from each other in polarity of a gradient pulse in the readout direction during acquisition, by using the correction amount.

2. The phase correction method according to claim 1, wherein the first k-space data and the second k-space data are one pair of data that are filled in a same k-space phase encoding line.

3. The phase correction method according to claim 1, wherein the first k-space data and the second k-space data are one pair of data that are filled in k-space phase encoding lines adjacent to each other.

4. The phase correction method according to claim 1, wherein the first k-space data and the second k-space data are data acquired during a pre-scan of MRI.

5. The phase correction method according to claim 1, wherein the first k-space data and the second k-space data are data acquired during a main scan of MRI.

6. The phase correction method according to claim 1, wherein:
a plurality of first k-space data and a plurality of second k-space data are acquired;
a plurality of first real space data are weighted to generate a plurality of first adjusted data with the predetermined weighting, the plurality of first real space data being obtained by performing one-dimensional Fourier transform on the plurality of first k-space data;
a plurality of second real space data are weighted to generate a plurality of second adjusted data with the predetermined weighting, the plurality of second real space data being obtained by performing one-dimensional Fourier transform on the plurality of second k-space data;
a plurality of correction amounts are calculated for correcting phase differences between the plurality of first adjusted data and the plurality of second adjusted data; and
phase differences between data that are different from each other in polarity of the gradient pulse in the readout direction during acquisition are corrected by using the plurality of correction amount.

7. The phase correction method according to claim 1, wherein the predetermined weighting gives a higher weight coefficient to a central region in the readout direction than to an outer region outside the central region.

8. The phase correction method according to claim 1, wherein the predetermined weighting converts a pixel value in a region outside an FOV (Field Of View) into a predetermined value.

9. The phase correction method according to claim 1, wherein the predetermined weighting is based on a Hamming window function in which center positions in the readout direction for acquiring the first k-space data and the second k-space data constitute a line-symmetric axis.

10. The phase correction method according to claim 1, wherein the predetermined weighting gives a higher weight coefficient to a region of interest than to a region of non-interest.

11. The phase correction method according to claim 10, further comprising acquiring information on a region of interest designated by a user,
wherein the predetermined weighting is set based on information on the region of interest.

12. The phase correction method according to claim 1, further comprising storing at least one of: one or plural arithmetic expressions; and a data table, for generating a plurality of types of weighting,
wherein the predetermined weighting minimizes a sum of phase differences between data that are different in polarity of the gradient pulse in the readout direction during acquisition among the plurality of types of weighting.

13. A phase correction apparatus comprising processing circuitry configured to:
acquire first k-space data acquired in a first readout direction and second k-space data acquired in a second readout direction that is opposite to the first readout direction;
weight first real space data to generate first adjusted data with a predetermined weighting, wherein weight coefficients in the predetermined weighting vary depending on a pixel position in a readout direction and become lower in a region where a variance of a phase difference is larger than a predetermined variance, the first real space data being obtained by performing one-dimensional Fourier transform on the first k-space data;
weight second real space data to generate second adjusted data with the predetermined weighting, the second real space data being obtained by performing one-dimensional Fourier transform on the second k-space data;
calculate a correction amount for correcting a phase difference between the first adjusted data and the second adjusted data; and
correct a phase difference between data that are different from each other in polarity of a gradient pulse in the readout direction during acquisition, by using the correction amount.

14. The phase correction apparatus according to claim 13, wherein the processing circuitry is configured to:
acquire a plurality of first k-space data and a plurality of second k-space data;
weight a plurality of first real space data to generate a plurality of first adjusted data with the predetermined weighting, the plurality of first real space data being obtained by performing one-dimensional Fourier transform on the plurality of first k-space data;
weight a plurality of second real space data to generate a plurality of second adjusted data with the predetermined weighting, the plurality of second real space data being obtained by performing one-dimensional Fourier transform on the plurality of second k-space data;
calculate a plurality of correction amounts for correcting phase differences between the plurality of first adjusted data and the plurality of second adjusted data; and
performs correction by using the plurality of correction amounts in such a manner that a sum of phase differences between data that are different from each other in polarity of the gradient pulse in the readout direction during acquisition is minimized.

15. The phase correction apparatus according to claim 13, further comprising a memory configured to store at least one of: one or plural arithmetic expressions; and a data table, for generating a plurality of types of weighting.

16. An MRI apparatus comprising:
a static magnetic field magnet configured to generate a static magnetic field;
a gradient coil configured to generate a gradient magnetic field; and
processing circuitry configured to
acquire first k-space data as data of MR signals by applying the gradient magnetic field in a first readout direction,
acquire second k-space data as data of MR signals by applying the gradient magnetic field in a second readout direction that is opposite to the first readout direction,
weight first real space data to generate first adjusted data with a predetermined weighting, wherein weight coefficients in the predetermined weighting vary depending on a pixel position in a readout direction and become lower in a region where a variance of a phase difference is larger than a predetermined variance, the first real space data being obtained by performing one-dimensional Fourier transform on the first k-space data;
weight second real space data to generate second adjusted data with the predetermined weighting, the second real space data being obtained by performing one-dimensional Fourier transform on the second k-space data,
calculate a correction amount for correcting a phase difference between the first adjusted data and the second adjusted data; and
correct a phase difference between data that are different from each other in polarity of the gradient magnetic field in the readout direction during acquisition, by using the correction amount.

17. The MRI apparatus according to claim 16, wherein the processing circuitry is configured to:
acquire the first k-space data and the second k-space data during a pre-scan;
acquire MR-image data for generating an MR image during a main scan; and
generate the MR image from the MR-image data that are corrected by using the correction amount.

18. The MRI apparatus according to claim 16, wherein the processing circuitry is configured to:
acquire the first k-space data, the second k-space data, and MR-image data for generating an MR image during a main scan; and
generate the MR image from the MR-image data that are corrected by using the correction amount.

19. The MRI apparatus according to claim 16, wherein the processing circuitry is configured to:
acquire a plurality of first k-space data and a plurality of second k-space data;
weight a plurality of first real space data to generate a plurality of first adjusted data with the predetermined weighting, the plurality of first real space data being obtained by performing one-dimensional Fourier transform on the plurality of first k-space data;
weight a plurality of second real space data to generate a plurality of second adjusted data with the predetermined weighting, the plurality of second real space data being obtained by performing one-dimensional Fourier transform on the plurality of second k-space data;
calculate a plurality of correction amounts for correcting phase differences between the plurality of first adjusted data and the plurality of second adjusted data; and
performs correction in such a manner that a sum of phase differences between data that are different from each other in polarity of the gradient magnetic field in the readout direction during acquisition is minimized by using the plurality of correction amounts.
